(19) United States
(12) Patent Application Publication
(10) Pub. No.: US 2026/0239925 A1
(43) Pub. Date: Aug. 13, 2026

(54) ELECTROSTATIC CHUCK AND SUBSTRATE FIXING DEVICE

(71) Applicant: SHINKO ELECTRIC INDUSTRIES CO., LTD., Nagano-shi (JP)

(72) Inventors: Ryuji Takahashi, Nagano (JP); Kohei Ogihara, Nagano (JP); Sakura Ando, Nagano (JP); Madoka Yamakami, Nagano (JP)

(21) Appl. No.: 19/536,690

(22) Filed: Feb. 11, 2026

(30) Foreign Application Priority Data
Feb. 13, 2025 (JP) 2025-021435

(51) Int. Cl. H10P 72/76; H10P 72/72

(52) U.S. Cl. CPC H10P 72/7616; H10P 72/72; H10P 72/7614

(57) ABSTRACT

An electrostatic chuck includes a base body having a first main surface and a second main surface opposite to the first main surface, and a porous body, in which a recessed portion recessed from the second main surface toward the first main surface and a plurality of through holes penetrating from a bottom surface of the recessed portion to the first main surface are formed in the base body, and the porous body is filled in the recessed portion.

### CROSS-REFERENCE TO RELATED APPLICATIONS

This application claims priority from Japanese Patent Application No. 2025-021435 filed on February 13, 2025, the contents of which are incorporated herein by reference.

### TECHNICAL FIELD

The present disclosure relates to an electrostatic chuck and a substrate fixing device.

### BACKGROUND ART

In the related art, a film formation apparatus (for example, a CVD apparatus, a PVD apparatus, and the like) and a plasma etching apparatus that are used when manufacturing a semiconductor device such as an IC and an LSI have a stage for accurately holding a wafer in a vacuum treatment chamber.

As such a stage, for example, a substrate fixing device is proposed which adsorbs and holds a wafer, which serves as a target object to be adsorbed, by an electrostatic chuck mounted on a base plate. An example of the substrate fixing device may have a structure in which a gas supply portion for cooling a wafer is provided. Gas is supplied to the surface of the electrostatic chuck, for example, through a gas flow channel inside the base plate and a porous ceramic body or a through hole provided in the electrostatic chuck.

### CITATION LIST

### Patent Literature

Patent Literature 1: US Patent No. 6,490,145

Patent Literature 2: JP2013-232641A

Patent Literature 3: WO2020/004478A1

### SUMMARY OF INVENTION

In an electrostatic chuck, discharge may occur within a gas hole through which gas flows.

An object of the present disclosure is to provide an electrostatic chuck and a substrate fixing device that can make it difficult for discharge to occur.

According to an aspect of the present disclosure, there is provided an electrostatic chuck including a base body having a first main surface and a second main surface opposite to the first main surface, and a porous body, in which the base body is formed with a recessed portion recessed from the second main surface toward the first main surface and a plurality of through holes penetrating from a bottom surface of the recessed portion to the first main surface, and the porous body is filled in the recessed portion.

According to the present disclosure, it is possible to make it difficult for discharge to occur.

### BRIEF DESCRIPTION OF DRAWINGS

FIG. 1 is a plan view illustrating a substrate fixing device according to an embodiment.

FIG. 2 is a cross-sectional view illustrating the substrate fixing device according to the embodiment.

FIG. 3 is a plan view illustrating a gas hole.

FIG. 4 is a cross-sectional view illustrating the gas hole.

FIG. 5 is a diagram illustrating a porous body.

FIGS. 6A and 6B are cross-sectional views illustrating a manufacturing method of a substrate fixing device according to an embodiment.

FIG. 7 is a cross-sectional view illustrating the manufacturing method of a substrate fixing device according to the embodiment.

FIG. 8 is a cross-sectional view illustrating an electrostatic chuck of a substrate fixing device according to Comparative Example.

### DESCRIPTION OF EMBODIMENTS

Embodiments of the present disclosure will be described in detail below with reference to the accompanying drawings. Note that, in the specification and drawings, the constitutional elements having substantially the same functional configurations are denoted with the same reference signs, and the redundant descriptions may be omitted.

### Structure of Substrate Fixing Device

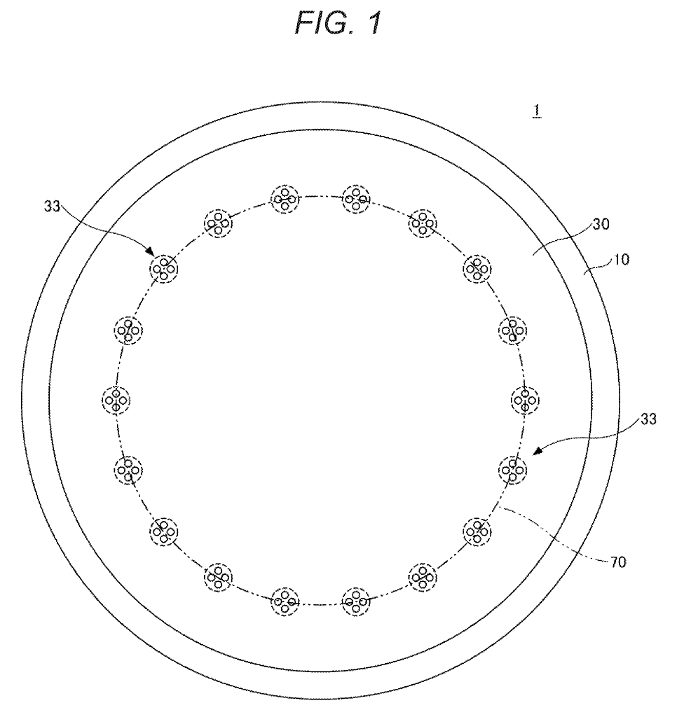

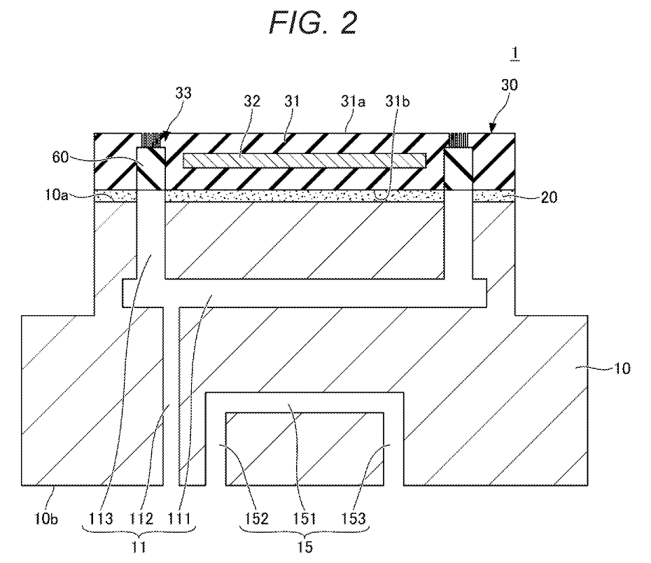

Embodiments relate to a substrate fixing device. FIG. 1 is a plan view illustrating a substrate fixing device according to an embodiment. FIG. 2 is a cross-sectional view illustrating the substrate fixing device according to the embodiment.

As illustrated in FIGS. 1 and 2, a substrate fixing device 1 according to an embodiment includes a base plate 10, an adhesive layer 20, and an electrostatic chuck 30.

The base plate 10 is a member for mounting the electrostatic chuck 30, and the electrostatic chuck 30 is fixed to the base plate 10. A thickness of the base plate 10 is about 20 mm to 40 mm, for example. The base plate 10 is formed of aluminum, for example, and may be used as an electrode for controlling plasma or the like. By supplying a predetermined high-frequency power to the base plate 10, the energy for causing ions or the like in a generated plasma state to collide with a wafer adsorbed on the electrostatic chuck 30 can be controlled, thereby effectively performing an etching process.

A gas supply portion 11 for supplying a gas to cool the wafer adsorbed and held on the electrostatic chuck 30 is provided in the base plate 10. The gas supply portion 11 includes a gas flow channel 111, a gas injection portion 112, and gas discharge portions 113.

The gas flow channel 111 is for example a hole formed in an annular shape in the base plate 10. The gas injection portion 112 is a hole having one end in communication with the gas flow channel 111 and the other end exposed to the outside from a lower surface 10b of the base plate 10, and serves to introduce an inert gas (e.g., He or Ar) into the gas flow channel 111 from the outside of the substrate fixing device 1. The gas discharge portion 113 is a hole having one end in communication with the gas flow channel 111 and the other end exposed to the outside from an upper surface 10a of the base plate 10, the hole penetrating through the adhesive layer 20, and serves to discharge the inert gas introduced into the gas flow channel 111. The gas discharge portions 113 are scattered in the upper surface 10a of the base plate 10 in a plan view. The number of gas discharge portions 113 may be determined as appropriate, as necessary, but is about several tens to several hundreds, for example. The gas discharge portions 113 are arranged at equal intervals on one circle, for example.

Note that the term 'plan view' refers to a view of a target object as viewed from the normal direction of the upper surface 10a of the base plate 10, that is, from the normal direction of a placement surface 31a of a base body 31 described below, and the term 'planar shape' refers to a shape of a target object as viewed from the normal direction of the upper surface 10a of the base plate 10.

In the base plate 10, a cooling mechanism 15 is provided. The cooling mechanism 15 includes a coolant flow channel 151, a coolant introduction portion 152, and a coolant discharge portion 153. The coolant flow channel 151 is for example a hole formed in an annular shape in the base plate 10. The coolant introduction portion 152 is a hole having one end in communication with the coolant flow channel 151 and the other end exposed to the outside from the lower surface 10b of the base plate 10, and serves to introduce a coolant (e.g., cooling water or fluorine-based fluid) into the coolant flow channel 151 from the outside of the substrate fixing device 1. The coolant discharge portion 153 is a hole having one end in communication with the coolant flow channel 151 and the other end exposed to the outside from the lower surface 10b of the base plate 10, and serves to discharge the coolant introduced into the coolant flow channel 151.

The cooling mechanism 15 is connected to a coolant control device (not illustrated) provided outside the substrate fixing device 1. The coolant control device (not illustrated) introduces a coolant into the coolant flow channel 151 from the coolant introduction portion 152, and discharges the coolant from the coolant discharge portion 153. The coolant can be circulated in the cooling mechanism 15 to cool the base plate 10, thereby cooling a wafer adsorbed on the electrostatic chuck 30.

The electrostatic chuck 30 is a part that adsorbs and holds a wafer, which is a target object to be adsorbed. A planar shape of the electrostatic chuck 30 is circular, for example. A diameter of the wafer, which is a target object to be adsorbed by the electrostatic chuck 30, is 203.2 mm (8 inches), 304.8 mm (12 inches), or 457.2 mm (18 inches), for example.

The electrostatic chuck 30 is provided on the upper surface 10a of the base plate 10 with the adhesive layer 20 interposed therebetween. The adhesive layer 20 is a silicone-based adhesive, for example. A thickness of the adhesive layer 20 is about 0.1 mm to 1.0 mm, for example. The adhesive layer 20 bonds the base plate 10 and the electrostatic chuck 30, and has an effect of reducing stress resulting from a difference in coefficient of thermal expansion between the electrostatic chuck 30 made of ceramic and the base plate 10 made of aluminum.

The electrostatic chuck 30 includes a base body 31, an electrostatic electrode 32, and a porous body 60. An upper surface of the base body 31 is a placement surface 31a for a target object to be adsorbed. A lower surface 31b of the base body 31 opposite to the placement surface 31a faces the base plate 10. The electrostatic chuck 30 is a Coulomb force-type electrostatic chuck, for example. The placement surface 31a is an example of a first main surface, and the lower surface 31b is an example of a second main surface.

The base body 31 is a dielectric body. For the base body 31, for example, ceramic such as aluminum oxide (Al2O3) or aluminum nitride (AlN) is used. The base body 31 may include, as auxiliary agents, oxides of two or more elements selected from silicon (Si), magnesium (Mg), calcium (Ca), aluminum (Al), and yttrium (Y). A thickness of the base body 31 is about 5 mm to 10 mm, for example, and a relative permittivity (1 kHz) of the base body 31 is about 9 to 10, for example. A volume resistivity of the base body 31 is 1×10¹⁵ Ω·m or more, for example.

The electrostatic electrode 32 is a thin film electrode, and is embedded in the base body 31. The electrostatic electrode 32 is connected to a power supply provided outside the substrate fixing device 1, and generates an adsorption force between the electrostatic electrode and the wafer by static electricity when a predetermined voltage is applied from the power supply. This makes it possible to adsorb and hold the wafer on the placement surface 31a of the base body 31 of the electrostatic chuck 30. The higher the voltage applied to the electrostatic electrode 32, the stronger the adsorption holding force. The electrostatic electrode 32 may have a unipolar shape or a bipolar shape. As a material of the electrostatic electrode 32, tungsten, molybdenum or the like is used, for example.

The base body 31 may be provided therein with a heating element that generates heat by applying a voltage from the outside of the substrate fixing device 1 and heats the placement surface 31a of the base body 31 to a predetermined temperature.

Gas holes 33 formed to penetrate the base body 31 and to expose the other ends of the gas discharge portions 113 are provided at positions corresponding to the respective gas discharge portions 113 of the base body 31. Through the gas holes 33, gas is supplied from the gas supply portion 11 to the placement surface 31a. As illustrated in FIG. 1, for example, a plurality of gas holes 33 are arranged at equal intervals on one circle 70.

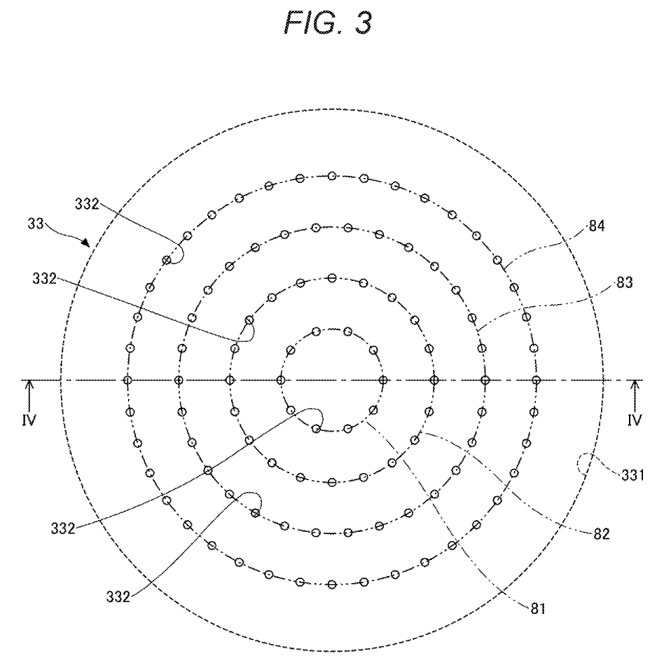

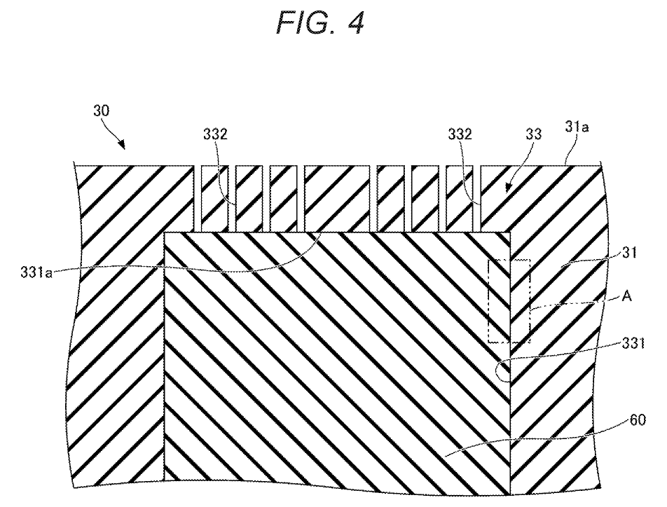

Here, the gas hole 33 will be described. FIG. 3 is a plan view illustrating the gas hole 33. FIG. 4 is a cross-sectional view illustrating the gas hole 33. FIG. 4 corresponds to a cross-sectional view taken along line IV-IV in FIG. 3.

As illustrated in FIGS. 2 to 4, each of the gas holes 33 has a recessed portion 331 recessed from the lower surface 31b of the base body 31 toward the placement surface 31a, and a plurality of through holes 332 penetrating from a bottom surface 331a of the recessed portion 331 to the placement surface 31a. The recessed portion 331 and the through holes 332 are in communication with each other. In a plan view, a size of the through hole 332 is smaller than that of the recessed portion 331. The number of through holes 332 per gas hole 33 is for example 10 to 200, preferably 50 to 150, and more preferably 75 to 125. When the plurality of gas holes 33 are arranged at equal intervals on one circle 70, the plurality of recessed portions 331 are also arranged at equal intervals on one circle 70.

As illustrated in FIG. 3, the plurality of through holes 332 are arranged on a plurality of concentric circles, for example, in a plan view. In an example, the plurality of through holes 332 are arranged on four concentric circles 81, 82, 83 and 84. It is preferable that intervals between the plurality of through holes 332 arranged on each of the circles 81, 82, 83 and 84 be constant for each of the circles 81, 82, 83 and 84.

A planar shape of each of the recessed portion 331 and the through hole 332 is circular, for example. An example in which the planar shape of each of the recessed portion 331 and the through hole 332 is circular will be described below. An inner diameter of the through hole 332 is smaller than that of the recessed portion 331. The inner diameter of the recessed portion 331 is about 1 mm to 5 mm, for example. The inner diameter of the through hole 332 is for example about 1 μm to 50 μm, preferably 20 μm to 40 μm, and more preferably 25 μm to 35 μm. As an example of a combination of the inner diameters of the recessed portion 331 and the through hole 332, the inner diameter of the recessed portion 331 is 2 mm, and the inner diameter of the through hole 332 is 30 μm. A depth of the recessed portion 331 is about 4 mm to 8 mm, for example. A depth of the through hole 332 is for example about 0.1 mm to 1 mm, preferably 0.2 mm to 0.8 mm, and more preferably 0.3 mm to 0.7 mm.

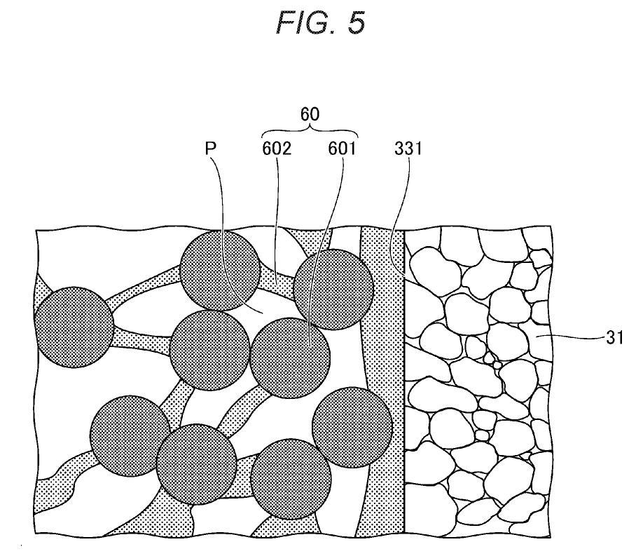

Here, the porous body 60 will be described. FIG. 5 is a diagram illustrating the porous body 60. FIG. 5 is a partial enlarged view of a portion A of FIG. 4.

As illustrated in FIG. 4, the porous body 60 is filled in the entire region within the recessed portion 331. In the through hole 332, the porous body 60 is not filled. As illustrated in FIG. 5, the porous body 60 includes a plurality of spherical oxide ceramic particles 601 and a mixed oxide 602 that binds and integrates the plurality of spherical oxide ceramic particles 601.

A diameter of the spherical oxide ceramic particle 601 is about 30 μm to 1000 μm, for example. A suitable example of the spherical oxide ceramic particle 601 is a spherical aluminum oxide particle. Additionally, it is preferable that the spherical oxide ceramic particles 601 be contained in the porous body 60 at a mass ratio of 80 mass% or more (97 mass% or less).

The mixed oxide 602 adheres to portions of outer surfaces (spherical surfaces) of the plurality of spherical oxide ceramic particles 601 and supports the particles. The mixed oxide 602 is formed of oxides of two or more elements selected from, for example, silicon (Si), magnesium (Mg), calcium (Ca), aluminum (Al), and yttrium (Y).

A plurality of pores P are formed inside the porous body 60. The pore P is in communication with the outside so that gas can flow through the porous body 60 from a lower side toward an upper side. It is preferable that the porosity of the pores P formed within the porous body 60 be about 20% to 50% of a total volume of the porous body 60. On inner surfaces of the pores P, portions of the outer surfaces of the spherical oxide ceramic particles 601 and the mixed oxide 602 are exposed.

Note that, when the base body 31 is formed of aluminum oxide, it is preferable that the base body 31 contain, as another component, oxides of two or more elements selected from silicon, magnesium, calcium, and yttrium. It is preferable that a compositional ratio of the oxides of two or more elements selected from silicon, magnesium, calcium, and yttrium in the base body 31 be the same as that of the oxides of two or more elements selected from silicon, magnesium, calcium, and yttrium in the mixed oxide 602 of the porous body 60.

In this manner, by making the compositional ratio of the oxides between the base body 31 and the mixed oxide 602 of the porous body 60 the same, no material transfer occurs between them during sintering of the porous body 60, so that flatness of the interface between the base body 31 and the porous body 60 can be ensured.

### Manufacturing Method of Substrate Fixing Device

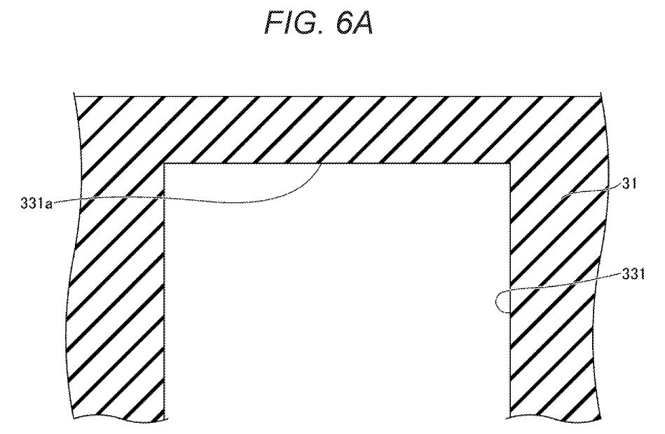

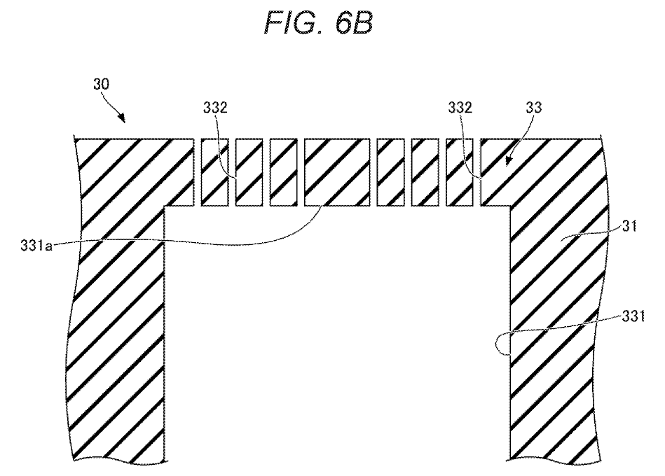

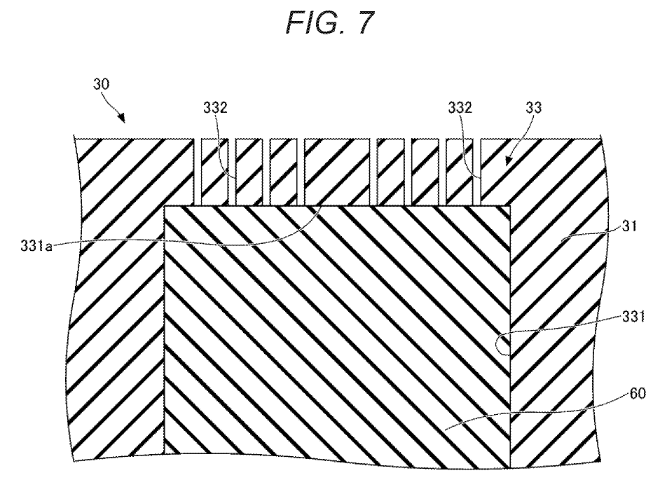

Next, a manufacturing method of the substrate fixing device 1 will be described. FIGS. 6A to 7 are cross-sectional views illustrating a manufacturing method of the substrate fixing device 1 according to an embodiment. FIGS. 6A to 7 illustrate cross sections corresponding to FIG. 4. Here, with reference to FIGS. 6A to 7, a process of forming the gas holes 33 in the electrostatic chuck 30, and the like will mainly be described.

First, a base body 31 having an electrostatic electrode 32 embedded therein is fabricated by a known manufacturing method including, for example, a process of processing a via in a green sheet, a process of filling the via with a conductive paste, a process of forming a pattern that becomes an electrostatic electrode, a process of stacking and firing another green sheet, a surface flattening process, and the like.

Next, as illustrated in FIG. 6A, recessed portions 331 recessed from a lower surface 31b of the base body 31 toward a placement surface 31a are formed. As described above, the recessed portion 331 has, for example, a circular planar shape, an inner diameter of about 1 mm to 5 mm, and a depth of about 4 mm to 8 mm. The recessed portions 331 are formed, for example, by drilling, at positions corresponding to gas discharge portions 113 of a base plate 10, in a number corresponding to the gas discharge portions 113.

Next, as illustrated in FIG. 6B, a plurality of through holes 332 penetrating from a bottom surface 331a of the recessed portion 331 to the placement surface 31a are formed. As described above, the through hole 332 has, for example, a circular planar shape, an inner diameter of about 1 μm to 50 μm, and a depth of about 0.1 mm to 1 mm. The through holes 332 are formed on a plurality of concentric circles by laser processing using, for example, a short-pulse deep ultraviolet (DUV) laser (see FIG. 3).

Next, as illustrated in FIG. 7, a porous body 60 is formed in the recessed portions 331. The porous body 60 may be formed by filling, using a squeegee or the like, a paste serving as a precursor of the porous body 60 into the recessed portions 331, followed by sintering. When a portion of the porous body 60 protrudes from the lower surface 31b of the base body 31, an end surface of the porous body 60 is made substantially flush with the lower surface 31b of the base body 31 by grinding or the like. Here, the through holes 332 are necessary for air escape when filling the paste serving as a precursor of the porous body 60 into the recessed portion 331, and serve to promote the filling of the paste. Note that a portion of the porous body 60 may enter the through holes 332, but the paste flows out if the inner diameter of the through holes 332 is large. Therefore, it is preferable that the inner diameter of the through holes 332 be appropriately reduced.

The paste serving as a precursor of the porous body 60 contains, for example, spherical aluminum oxide particles at a predetermined mass ratio. The remainder of the paste includes oxides of two or more elements selected from, for example, silicon, magnesium, calcium, aluminum, and yttrium, and additionally includes an organic binder or solvent. As the organic binder, for example, polyvinyl butyral may be used. As the solvent, for example, alcohol may be used.

Next, a base plate 10 in which a cooling mechanism 15 and the like are formed in advance is prepared, and an adhesive layer 20 (uncured) is formed on the base plate 10. Then, the structure illustrated in FIG. 7 is placed on the base plate 10 with the adhesive layer 20 interposed therebetween, and the adhesive layer 20 is cured.

In this way, the substrate fixing device 1 can be manufactured.

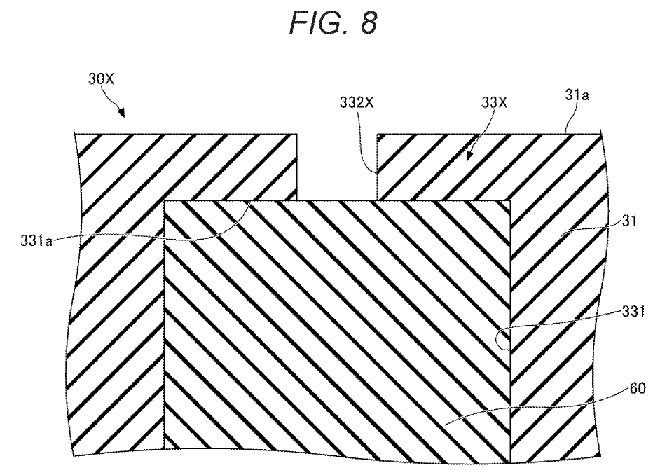

Here, effects exhibited by the substrate fixing device 1 will be described with reference to Comparative Example. FIG. 8 is a cross-sectional view illustrating an electrostatic chuck of a substrate fixing device according to Comparative Example. As illustrated in FIG. 8, an electrostatic chuck 30X of a substrate fixing device according to Comparative Example is different from the electrostatic chuck 30 of the substrate fixing device 1 (see FIGS. 1 to 4) in that the gas hole 33 is replaced with a gas hole 33X.

Each of the gas holes 33X includes a recessed portion 331 and one through hole 332X penetrating from the bottom surface 331a of the recessed portion 331 to the placement surface 31a. The recessed portion 331 and the through hole 332X are, for example, provided concentrically and are in communication with each other. In a plan view, a size of the through hole 332X is smaller than that of the recessed portion 331. For example, an inner diameter of the recessed portion 331 is 2 mm, and an inner diameter of the through hole 332X is 300 μm.

When the number of through holes 332 per gas hole 33 of the substrate fixing device 1 is 100 and the inner diameter thereof is 30 μm, the total area (π × (15 μm)² × 100) of the through holes 332 per gas hole 33 of the substrate fixing device 1 in a plan view is equal to the area (π × (150 μm)²) of the through hole 332X of the gas hole 33X of the substrate fixing device according to Comparative Example. Therefore, when the flow rate of gas supplied from the gas supply portion 11 is the same, the flow rate of gas supplied to the placement surface 31a through the gas hole 33 and the flow rate of gas supplied to the placement surface 31a through the gas hole 33X are the same. On the other hand, the flow rate of gas flowing through each of the through holes 332 is 1/100 of the flow rate of gas flowing through the through hole 332X, and discharge is less likely to occur within the through hole 332 than within the through hole 332X. In this way, according to the present embodiment, it is possible to make it difficult for discharge to occur while avoiding a decrease in cooling efficiency.

In addition, when the plurality of through holes 332 are arranged on the plurality of concentric circles 81 to 84 in a plan view, isotropy of gas flow around each gas hole 33 is high, and good uniformity in cooling efficiency can be achieved. In particular, if the intervals between the plurality of through holes 332 arranged on the same circle are constant, even better uniformity in cooling efficiency can be achieved. In addition, when the plurality of recessed portions 331 are arranged at equal intervals on one circle 70 in a plan view, isotropy of gas flow over the entire placement surface 31a is high, and good uniformity in cooling efficiency can be achieved.

Although the preferred embodiments have been described in detail, the present disclosure is not limited to the above-described embodiments, and a variety of changes and replacements can be made for the above-described embodiments without departing from the scope defined in the claims.

What is claimed is:

1. An electrostatic chuck comprising:
a base body having a first main surface and a second main surface opposite to the first main surface; and
a porous body, wherein
the base body is formed with a recessed portion recessed from the second main surface toward the first main surface, and a plurality of through holes penetrating from a bottom surface of the recessed portion to the first main surface, and
the porous body is filled in the recessed portion.

2. The electrostatic chuck according to claim 1, wherein, in a plan view, the plurality of through holes are arranged on a plurality of concentric circles.

3. The electrostatic chuck according to claim 2, wherein intervals between the plurality of through holes arranged on the same circle are constant.

4. The electrostatic chuck according to claim 1, wherein a volume resistivity of the base body is 1×10¹⁵ Ω·m or more.

5. The electrostatic chuck according to claim 1, wherein
the porous body has a plurality of pores in communication with each other, and
gas flows from the second main surface toward the first main surface through the plurality of pores in communication with each other.

6. The electrostatic chuck according to claim 1, wherein the base body and the porous body include the same oxide ceramic.

7. The electrostatic chuck according to claim 6, wherein the oxide ceramic is aluminum oxide.

8. The electrostatic chuck according to claim 1, wherein
the base body and the porous body include oxides of the same two or more elements, and
a compositional ratio of the oxides in the base body is the same as that of the oxides in the porous body.

9. The electrostatic chuck according to claim 8, wherein the two or more elements are selected from silicon, magnesium, calcium, and yttrium.

10. The electrostatic chuck according to claim 1, wherein, in a plan view, a plurality of the recessed portions are arranged at equal intervals on one circle.

11. A substrate fixing device comprising:
a base plate comprising a gas supply portion therein; and
the electrostatic chuck according to claim 1 fixed to the base plate, wherein
the second main surface faces the base plate, and
gas is supplied from the gas supply portion toward the recessed portion.
